(19) United States
(12) Patent Application Publication
(10) Pub. No.: US 2014/0027728 A1
(43) Pub. Date: Jan. 30, 2014

(54) ORGANIC LIGHT EMITTING DIODE DISPLAY AND MANUFACTURING METHOD THEREOF

(71) Applicant: SAMSUNG DISPLAY CO., LTD., Yongin-City (KR)

(72) Inventors: JU-WON YOON, Yongin-City (KR); IL-JEONG LEE, Yongin-City (KR); CHOONG-YOUL IM, Yongin-City (KR); DO-HYUN KWON, Yongin-City (KR); MOO-SOON KO, Yongin-City (KR); MIN-WOO WOO, Yongin-City (KR)

(73) Assignee: Samsung Display Co., Ltd., Yongin-City (KR)

(21) Appl. No.: 13/757,965

(22) Filed: Feb. 4, 2013

(30) Foreign Application Priority Data
Jul. 25, 2012 (KR) 10-2012-0081369

(51) Int. Cl. H01L 51/52; H01L 51/56; H01L 33/08

(52) U.S. Cl. CPC H01L 51/5203; H01L 33/08; H01L 51/56
USPC 257/40; 257/88; 438/34

(57) ABSTRACT

An organic light emitting diode display includes a substrate, a scan line formed on the substrate and transferring a scan signal, a data line and a driving voltage line crossing the scan line and transferring a data signal and a driving voltage, respectively, a switching thin film transistor connected to the scan line and the data line, a driving thin film transistor connected to the switching thin film transistor and the driving voltage line, and an organic light emitting diode connected to the driving thin film transistor. The driving thin film transistor includes a driving semiconductor layer, a first gate insulating layer covering the driving semiconductor layer, a floating gate electrode formed on the first gate insulating layer, a second gate insulating layer, and a driving gate electrode formed on the second gate insulating layer.

### CLAIM OF PRIORITY

This application makes reference to, incorporates the same herein, and claims all benefits accruing under 35 U.S.C. §119 from an application for ORGANIC LIGHT EMITTING DIODE DISPLAY AND MANUFACTURING METHOD THEREOF earlier filed in the Korean Intellectual Property Office on 25 Jul. 2012 and there duly assigned Serial No. 10-2012-0081369.

### BACKGROUND OF THE INVENTION

1. Field of the Invention

The present invention relates generally to an organic light emitting diode (OLED) display and a manufacturing method thereof.

2. Description of the Related Art

An organic light emitting diode display includes two electrodes and an organic emission layer interposed therebetween, electrons injected from one electrode and holes injected from the other electrode are bonded to each other in the organic emission layer to form an exciton, and light is emitted while the exciton discharges energy.

The organic light emitting diode display includes a plurality of pixels including an organic light emitting diode that is a self-light emitting element, and a plurality of thin film transistors and at least one capacitor for driving the organic light emitting diode are formed in each pixel. A plurality of thin film transistors basically includes a switching thin film transistor and a driving thin film transistor.

In the switching thin film transistor, a gate insulating layer having a small thickness is formed between the gate electrode and the semiconductor layer to obtain a rapid switching operation. In this case, since the thickness of the gate insulating layer of the driving thin film transistor formed on the same layer as the switching thin film transistor is reduced, a driving range of a gate voltage applied to the gate electrode of the driving thin film transistor becomes narrow. Therefore, it is difficult to control the magnitude of the gate voltage Vgs of the driving thin film transistor so that a lot of grayscales are ensured.

The above information disclosed in this Background section is only for enhancement of understanding of the background of the described technology, and therefore it may contain information that does not form the prior art that is already known in this country to a person of ordinary skill in the art.

### SUMMARY OF THE INVENTION

The present invention has been developed in an effort to provide an organic light emitting diode display which broadens a driving range of a driving thin film transistor to display a lot of grayscales, and a manufacturing method thereof.

An exemplary embodiment provides an organic light emitting diode display including a substrate, a scan line formed on the substrate and transferring a scan signal, a data line and a driving voltage line crossing the scan line and transferring a data signal and a driving voltage, respectively, a switching thin film transistor connected to the scan line and the data line, a driving thin film transistor connected to the switching thin film transistor and the driving voltage line, and an organic light emitting diode connected to the driving thin film transistor. The driving thin film transistor may include a driving semiconductor layer including a driving channel region, and a driving source region and a driving drain region with the driving channel region interposed therebetween, a first gate insulating layer covering the driving semiconductor layer, a floating gate electrode formed on the first gate insulating layer and formed at a position corresponding to the driving channel region, a second gate insulating layer covering the first gate insulating layer and the floating gate electrode, and a driving gate electrode formed on the second gate insulating layer and formed at a position corresponding to the floating gate electrode.

A width of the driving gate electrode may be the same as or smaller than the width of the floating gate electrode.

A difference between the width of the driving gate electrode and the width of the floating gate electrode may be 4 ?m or less.

When a first floating capacitor formed between the driving gate electrode and the floating gate electrode is defined by C1 and a second floating capacitor formed between the floating gate electrode and the drain region is defined by C2, C2/C1 (a ratio of the first floating capacitor) and the second floating capacitor may be more than 0 and less than 2.

The switching thin film transistor may include a switching semiconductor layer including a switching channel region, a switching source region and a switching drain region, with the switching channel region interposed therebetween, and a switching gate electrode formed on the first gate insulating layer covering the switching semiconductor layer and formed at a position corresponding to the switching channel region, and the first gate insulating layer and the floating gate electrode may cover the second gate insulating layer.

The switching gate electrode may be connected to the scan line, and the floating gate electrode may be separated from the scan line.

Another exemplary embodiment provides a manufacturing method of an organic light emitting diode display, including: forming a switching semiconductor layer and a driving semiconductor layer on a substrate, forming a first gate insulating layer covering the switching semiconductor layer and the driving semiconductor layer, forming a switching gate electrode and a floating gate electrode at positions partially overlapping the switching semiconductor layer and the driving semiconductor layer, respectively, on the first gate insulating layer, doping an impurity on the switching semiconductor layer and the driving semiconductor layer by using the switching gate electrode and the floating gate electrode as a mask to form a switching source region, a switching drain region, a driving source region and a driving drain region, respectively, forming a second gate insulating layer covering the first gate insulating layer, the switching gate electrode, and the floating gate electrode, and forming a driving gate electrode at a position corresponding to the floating gate electrode on the second gate insulating layer.

Impurity doping concentrations of the switching source region, the switching drain region, the driving source region, and the driving drain region may be the same as each other.

The switching gate electrode may be connected to a scan line transferring a scan signal and may be formed on the same layer as the scan line.

The floating gate electrode may be formed so as to be separated from the scan line.

The manufacturing method may further include: forming an interlayer insulating layer on the second gate insulating layer and the driving gate electrode, forming a data line and a driving voltage line crossing the scan line and transferring a data signal and a driving voltage, respectively, on the interlayer insulating layer, forming a protective layer covering upper portions of the data line and the driving voltage line, and forming an organic light emitting diode connected to the driving thin film transistor on the protective layer.

According to the exemplary embodiments, it is possible to form a driving semiconductor layer so that an impurity doping concentration of the driving semiconductor layer is the same as that of a switching semiconductor layer, while broadening a driving range by forming a floating gate electrode on the driving semiconductor layer to perform an impurity doping process, and forming a second gate insulating layer and a driving gate electrode on the floating gate electrode so as to overlap each other.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is an equivalent circuit of one pixel of an organic light emitting diode display according to an exemplary embodiment.

FIG. 2 is a view schematically showing positions of a plurality of thin film transistors and capacitors in one pixel of the organic light emitting diode display according to the exemplary embodiment.

FIG. 3 is a specific layout view of one pixel of the organic light emitting diode display according to the exemplary embodiment.

FIG. 4 is a cross-sectional view taken along line IV-IV of the organic light emitting diode display of FIG. 3.

FIG. 5 is a cross-sectional view taken along line V-V of the organic light emitting diode display of FIG. 3.

FIG. 6 is a view schematically showing a first floating capacitor and a second floating capacitor of the organic light emitting diode display according to the exemplary embodiment.

FIG. 7 is a graph showing a driving current according to a driving drain voltage applied to a driving drain electrode of a driving thin film transistor in the organic light emitting diode display according to the exemplary embodiment, and FIG. 8 is a graph showing a driving current according to a driving drain voltage applied to a driving drain electrode of a driving thin film transistor in a known organic light emitting diode display.

FIGS. 9 to 11 are cross-sectional views sequentially showing a manufacturing method of a switching thin film transistor and a driving thin film transistor of the organic light emitting diode display according to the exemplary embodiment.

### DETAILED DESCRIPTION OF THE INVENTION

Hereinafter, the present invention will be described more fully hereinafter with reference to the accompanying drawings, in which exemplary embodiments of the invention are shown. As those skilled in the art will realize, the described embodiments may be modified in various different ways, all without departing from the spirit or scope of the present invention.

The drawings and description are to be regarded as illustrative in nature and not restrictive. Like reference numerals designate like elements throughout the specification.

Furthermore, the size and thickness of each component shown in the drawings are arbitrarily shown for understanding and ease of description, but the present invention is not limited thereto.

In the drawings, the thickness of layers, films, panels, regions, etc. are exaggerated for clarity. In the drawings, for understanding and ease of description, the thickness of some layers and areas is exaggerated. It will be understood that, when an element such as a layer, film, region, or substrate is referred to as being “on” another element, it can be directly on the other element or intervening elements may also be present.

Furthermore, in the specification, unless explicitly described to the contrary, the word “comprise” and variations such as “comprises” or “comprising” will be understood to imply the inclusion of stated elements but not the exclusion of any other elements. In addition, in the specification, the word “_on” means positioning on or below the object portion, but does not essentially mean positioning on the upper side of the object portion based on a gravity direction.

Moreover, an active matrix (AM) type organic light emitting diode display having a 6Tr-2Cap structure, including one pixel, six thin film transistors (TFT), and two capacitors, is shown in the accompanying drawings, but the present invention is not limited thereto. Accordingly, the organic light emitting diode display may include one pixel, a plurality of thin film transistors, and at least one capacitor, and a separate wire may be further formed or a known wire may be omitted to provide various structures. Here, the pixel means a minimum unit displaying an image, and the organic light emitting diode display displays the image through a plurality of pixels.

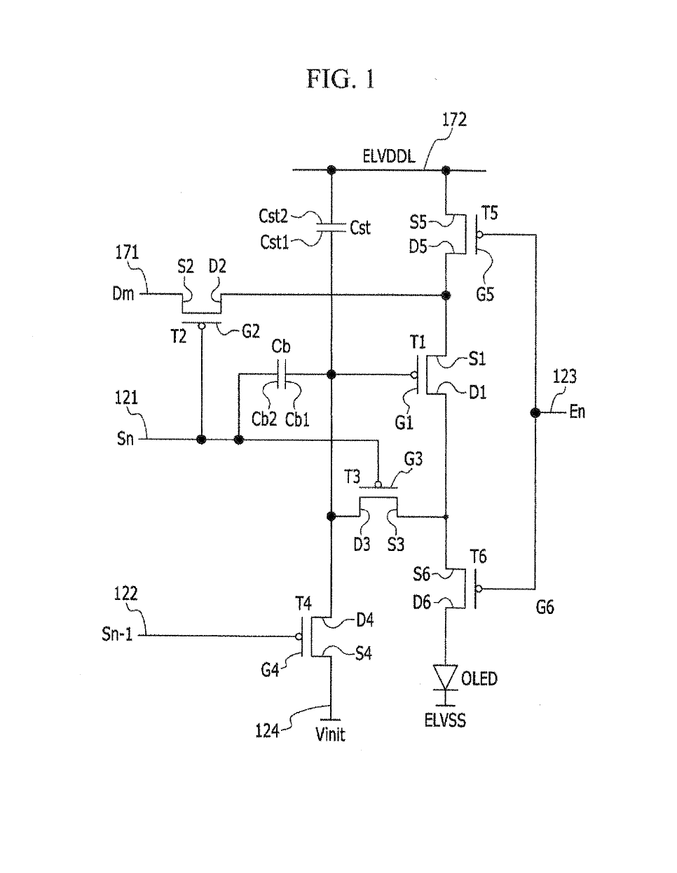

An organic light emitting diode display according to an exemplary embodiment will now be described in detail with reference to FIGS. 1 to 5.

FIG. 1 is an equivalent circuit of one pixel of an organic light emitting diode display according to an exemplary embodiment.

As shown in FIG. 1, one pixel of the organic light emitting diode display according to the exemplary embodiment includes a plurality of signal lines 121, 122, 123, 124, 171, and 172, and a plurality of thin film transistors T1, T2, T3, T4, T5, and T6, capacitors Cst and Cb, and an organic light emitting diode (OLED) connected to a plurality of signal lines.

The thin film transistors include a driving thin film transistor T1, a switching thin film transistor T2, a compensation thin film transistor T3, an initialization thin film transistor T4, a first light emission control thin film transistor T5, and a second light emission control thin film transistor T6, and the capacitors Cst and Cb include a storage capacitor Cst and a boosting capacitor Cb.

The signal line includes a scan line 121 transferring a scan signal Sn, a prior scan line 122 transferring a prior scan signal Sn-1 to the initialization thin film transistor T4, a light emission control line 123 transferring a light emission control signal En to the first light emission control thin film transistor T5 and the second light emission control thin film transistor T6, a data line 171 crossing the scan line 121 and transferring a data signal Dm, a driving voltage line 172 transferring a driving voltage ELVDD and formed almost in parallel to the data line 171, and an initialization voltage line 124 transferring an initialization voltage Vimit initializing the driving thin film transistor T1.

A gate electrode G1 of the driving thin film transistor T1 is connected to an end Cst1 of the storage capacitor Cst, a source electrode S1 of the driving thin film transistor T1 is connected via the first light emission control thin film transistor 15 to the driving voltage line 172, a drain electrode D1 of the driving thin film transistor T1 is electrically connected via the second light emission control thin film transistor T6 to an anode of the organic light emitting diode (OLED). The driving thin film transistor T1 receives the data signal Dm according to switching operation of the switching thin film transistor T2 so as to supply a driving current to the organic light emitting diode (OLED).

A gate electrode G2 of the switching thin film transistor T2 is connected to the scan line 121, a source electrode S2 of the switching thin film transistor T2 is connected to the data line 171, and a drain electrode D2 of the switching thin film transistor T2 is connected via the first light emission control thin film transistor 15 to the driving voltage line 172 while being connected to the source electrode S1 of the driving thin film transistor T1. The switching thin film transistor T2 is turned-on according to the scan signal Sn transferred through the scan line 121 so as to perform a switching operation transferring the data signal Dm on the data line 171 to the source electrode 51 of the driving thin film transistor T1.

A gate electrode G3 of the compensation thin film transistor T3 is connected to the scan line 121, a source electrode S3 of the compensation thin film transistor T3 is connected to the drain electrode D1 of the driving thin film transistor T1 and, via the second light emission control thin film transistor T6, to the anode of the organic light emitting diode (OLED), and a drain electrode D3 of the compensation thin film transistor T3 is connected to an end Cb1 of the boosting capacitor Cb and to a drain electrode D4 of the initialization thin film transistor T4. The compensation thin film transistor T3 is turned-on according to the scan signal Sn transferred through the scan line 121 so as to connect the gate electrode G1 and the drain electrode D1 of the driving thin film transistor T1 to each other, thus performing diode-connection of the driving thin film transistor T1. Therefore, a driving current flows through the diode-connected driving thin film transistor T1.

A gate electrode G4 of the initialization thin film transistor T4 is connected to the prior scan line 122, a source electrode S4 of the initialization thin film transistor T4 is connected to the initialization voltage line 124, and a drain electrode D4 of the initialization thin film transistor T4 is connected to an end Cb1 of the boosting capacitor Cb, to an end Cst1 of the storage capacitor Cst, to a drain electrode D3 of the compensation thin film transistor T3, and to the gate electrode G1 of the driving thin film transistor T1. The initialization thin film transistor T4 is turned-on according to the prior scan signal Sn-1 transferred through the prior scan line 122 so as to transfer the initialization voltage Vinit to the gate electrode G1 of the driving thin film transistor T1, thus performing an initialization operation initializing the voltage of the gate electrode G1 of the driving thin film transistor T1.

A gate electrode G5 of the first light emission control thin film transistor T5 is connected to the light emission control line 123, a source electrode S5 of the first light emission control thin film transistor T5 is connected to the driving voltage line 172, and a drain electrode D5 of the first light emission control thin film transistor T5 is connected to the source electrode S1 of the driving thin film transistor T1 and to the drain electrode S2 of the switching thin film transistor T2.

A gate electrode G6 of the second light emission control thin film transistor T6 is connected to the light emission control line 123, a source electrode S6 of the second light emission control thin film transistor T6 is connected via the driving thin film transistor T1 to the drain electrode D5 of the first light emission control thin film transistor T5, and a drain electrode D6 of the second light emission control thin film transistor T6 is electrically connected to the anode of the organic light emitting diode (OLED). The first light emission control thin film transistor 15 and the second light emission control thin film transistor T6 are turned-on according to the light emission control signal En transferred through the light emission control line 123 so as to transfer the driving voltage ELVDD to the organic light emitting diode (OLED), thus allowing the driving current to flow in the organic light emitting diode (OLED).

The scan line 121 connected to the gate electrode G2 of the switching thin film transistor T2 is connected to another end Cb2 of the boosting capacitor Cb, and an end Cb 1 of the boosting capacitor Cb is connected to the gate electrode G1 of the driving thin film transistor T1.

Another end Cst2 of the storage capacitor Cst is connected to the driving voltage line 172, and a cathode of the organic light emitting diode (OLED) is connected to a common voltage ELVSS. Accordingly, the organic light emitting diode (OLED) receives a driving current Id from the driving thin film transistor T1, via the second light emission control thin film transistor T6, so as to emit light, thereby displaying an image.

Hereinafter, a specific operational process of one pixel of the organic light emitting diode display according to the exemplary embodiment will be described in detail.

First, a prior scan signal Sn-1 of a low level is supplied through the prior scan line 122 during an initialization period. Then, the initialization thin film transistor T4 is turned-on in correspondence to the prior scan signal Sn-1 of the low level, and the initialization voltage Vint is supplied from the initialization voltage line 124 through the initialization thin film transistor T4 to the driving thin film transistor T1 so as to initialize the driving thin film transistor T1.

Subsequently, the scan signal Sn of the low level is supplied through the scan line 121 during a data programming period. Then, the switching thin film transistor T2 and the compensation thin film transistor T3 are turned-on in correspondence to the scan signal Sn of the low level.

In this case, the driving thin film transistor T1 is turned-on in a diode-connection form by the compensation thin film transistor T3, and particularly, since the driving thin film transistor T1 is initialized during the aforementioned initialization period, the driving thin film transistor T1 is diode-connected in a forward direction. Therefore, the data signal Dm supplied from the data line 171 goes via the switching thin film transistor T2, the driving thin film transistor T1, and the compensation thin film transistor T3, so that a voltage corresponding to a difference between the data signal Dm and a threshold voltage Vth of the driving thin film transistor T1 is stored in the storage capacitor Cst.

Subsequently, if supply of the scan signal Sn is stopped and the level of the voltage of the scan signal Sn is changed to a high level, the voltage applied to the gate electrode G1 of the driving thin film transistor T1 is changed in correspondence to a fluctuation width of the voltage of the scan signal Sn by a coupling action of the boosting capacitor Cb. In this case, since the voltage applied to the gate electrode G1 of the driving thin film transistor T1 is changed by charge sharing between the storage capacitor Cst and the boosting capacitor Cb, a change amount of the voltage applied to the driving gate electrode G1 fluctuates in proportion to a fluctuation width of the voltage of the scan signal Sn and a charge sharing value between the storage capacitor Cst and the boosting capacitor Cb.

Subsequently, the level of the light emission control signal En supplied from the light emission control line 123 during the light emission period is changed from the high level to the low level. Then, the first light emission control thin film transistor T5 and the second light emission control thin film transistor T6 are turned-on by the light emission control signal En of the low level during the light emission period. Thereby, the driving voltage ELVDD goes through the driving voltage line 172 via the first light emission control thin film transistor T5, the driving thin film transistor T1, the second light emission control thin film transistor T6, and the organic light emitting diode (OLED) so as to allow the driving current to flow through a path to the common voltage ELVSS.

The driving current is controlled by the driving thin film transistor T1, and the driving thin film transistor T1 generates a driving current having the magnitude corresponding to the voltage supplied to the gate electrode G1 thereof. In this case, since the voltage reflecting the threshold voltage of the driving thin film transistor T1 is stored in the storage capacitor Cst during the aforementioned data programming period, the threshold voltage of the driving thin film transistor T1 is compensated during the light emission period.

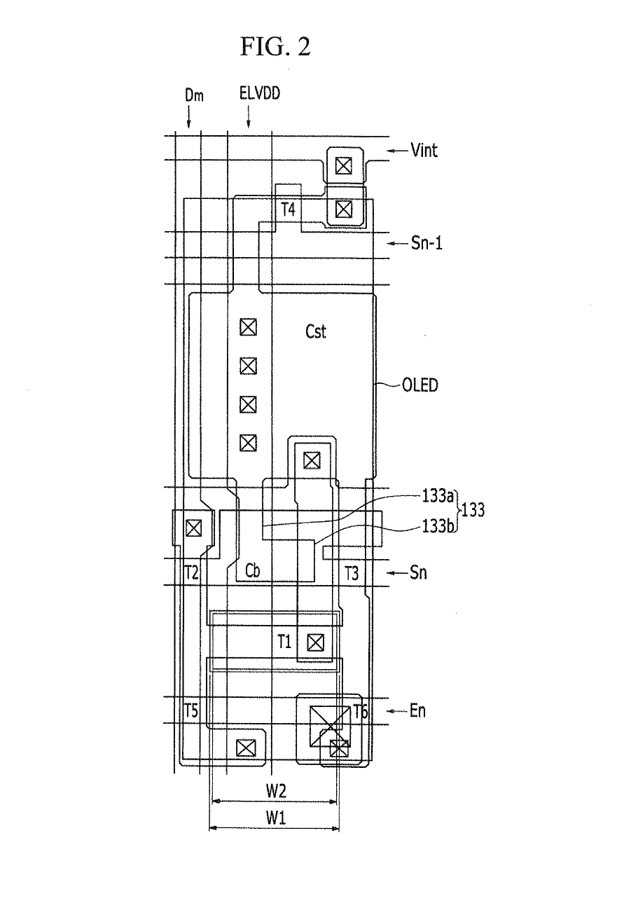

A detailed structure of the pixel of the organic light emitting diode display shown in FIG. 1 will now be described in detail with reference to FIGS. 2 to 5 together with FIG. 1.

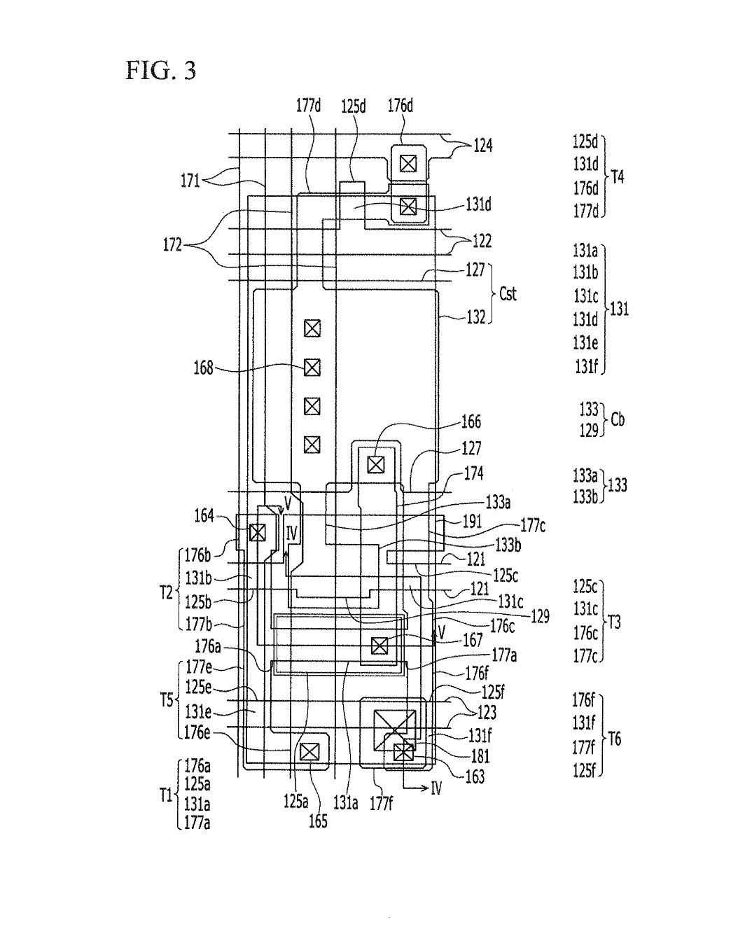

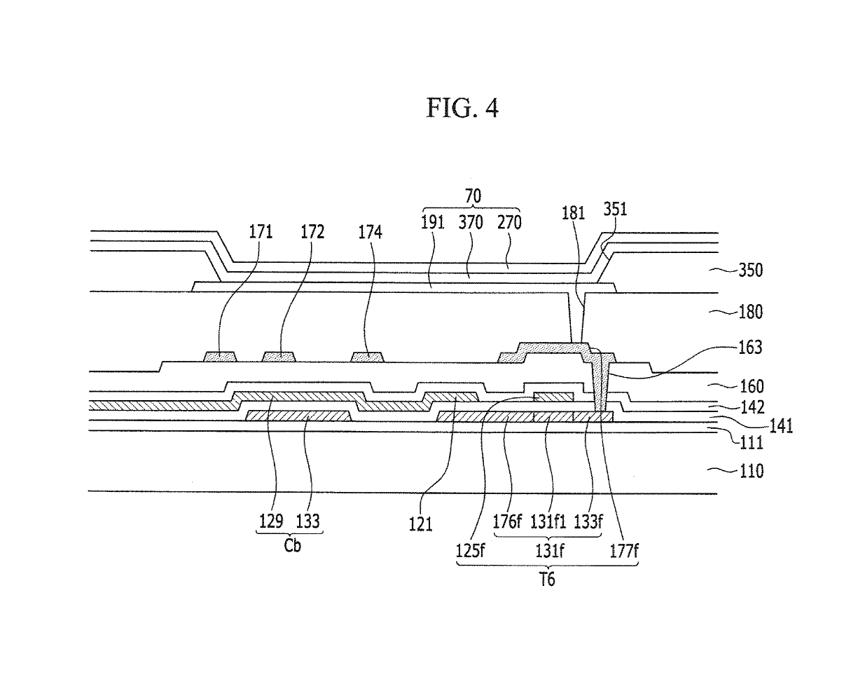

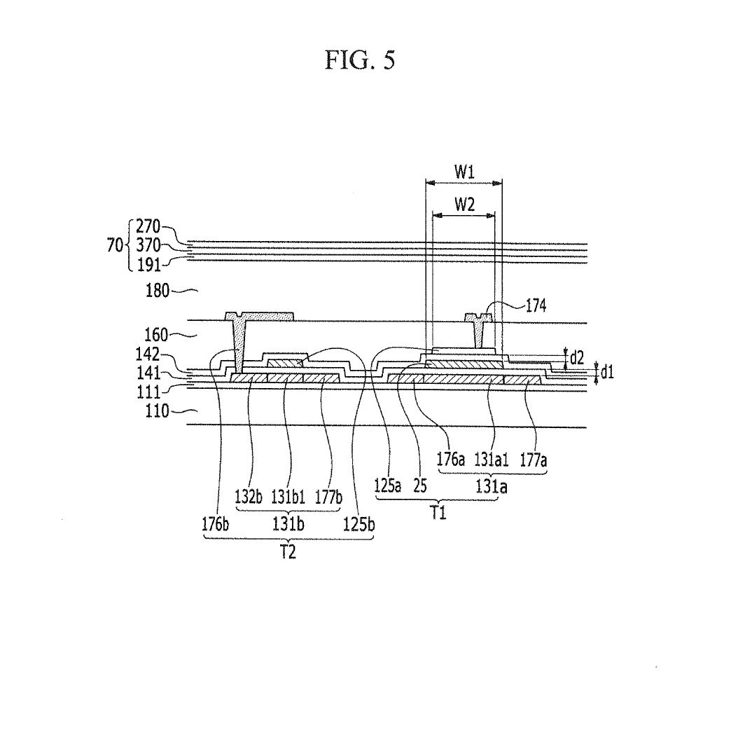

FIG. 2 is a view schematically showing positions of a plurality of thin film transistors and capacitors in one pixel of the organic light emitting diode display according to the exemplary embodiment, FIG. 3 is a specific layout view of one pixel of the organic light emitting diode display according to the exemplary embodiment, FIG. 4 is a cross-sectional view taken along line IV-IV of the organic light emitting diode display of FIG. 3, and FIG. 5 is a cross-sectional view taken along line V-V of the organic light emitting diode display of FIG. 3.

As shown in FIGS. 2 to 5, the pixel of the organic light emitting diode display according to the exemplary embodiment includes the scan line 121, the prior scan line 122, the light emission control line 123, and the initialization voltage line 124 applying the scan signal Sn, the prior scan signal Sn-1, the light emission control signal En, and the initialization voltage Vint, respectively, and formed in a row direction, and the data line 171 and the driving voltage line 172 crossing each of the scan line 121, the prior scan line 122, the light emission control line 123, and the initialization voltage line 124 and applying the data signal Dm and the driving voltage ELVDD, respectively, to the pixel.

Furthermore, in the pixel, the driving thin film transistor T 1, the switching thin film transistor T2, the compensation thin film transistor T3, the initialization thin film transistor T4, the first light emission control thin film transistor T5, the second light emission control thin film transistor T6, the storage capacitor Cst, the boosting capacitor Cb, and the organic light emitting diode (OLED) 70 are formed.

The driving thin film transistor T1, the switching thin film transistor T2, the compensation thin film transistor T3, the initialization thin film transistor T4, the first light emission control thin film transistor T5, and the second light emission control thin film transistor T6 are formed along the semiconductor layer 131, and the semiconductor layer 131 is bent to have various shapes. The semiconductor layer 131 is formed of polysilicon, and includes a channel region not doped with an impurity, and a source region and a drain region formed at both sides of the channel region to be doped with the impurity. Herein, the impurity is changed according to a kind of thin film transistor, and an N type impurity or a P type impurity is feasible. The semiconductor layer includes a driving semiconductor layer 131a formed in the driving thin film transistor T1, a switching semiconductor layer 131b formed in the switching thin film transistor T2, a compensation semiconductor layer 131c formed in the compensation thin film transistor T3, an initialization semiconductor layer 131d formed in the initialization thin film transistor T4, and a first light emission control semiconductor layer 131e and a second light emission control semiconductor layer 131f formed in the first light emission control thin film transistor T5 and the second light emission control thin film transistor T6, respectively.

The driving thin film transistor T1 includes the driving semiconductor layer 131a, the driving gate electrode 125a, the driving source electrode 176a, and the driving drain electrode 177a. The driving source electrode 176a corresponds to the driving source region 176a doped with the impurity in the driving semiconductor layer 131a, and the driving drain electrode 177a corresponds to the driving drain region 177a doped with the impurity in the driving semiconductor layer 131a. A floating gate electrode 25 is formed beneath the driving gate electrode 125a so as to overlap the driving gate electrode 125a. The floating gate electrode 25 is formed on the same layer as a switching gate electrode 125b, a compensation gate electrode 125c, a first light emission control gate electrode 125e, a second light emission control gate electrode 125f, the scan line 121, the prior scan line 122, and the light emission control line 123.

The switching thin film transistor T2 includes the switching semiconductor layer 131b, the switching gate electrode 125b, the switching source electrode 176b, and the switching drain electrode 177b. The switching drain electrode 177b corresponds to the switching drain region 177b doped with the impurity in the switching semiconductor layer 131b.

The compensation thin film transistor T3 includes the compensation semiconductor layer 131c, the compensation gate electrode 125c, the compensation source electrode 176c, and the compensation drain electrode 177c, the compensation source electrode 176c corresponding to the compensation source region doped with the impurity in the compensation semiconductor layer 131c, and the compensation drain electrode 177c corresponding to the compensation drain region doped with the impurity in the compensation semiconductor layer 131c.

The initialization thin film transistor T4 includes the initialization semiconductor layer 131d, the initialization gate electrode 125d, the initialization source electrode 176d, and the initialization drain electrode 177d. The initialization drain electrode 177d corresponds to the initialization drain region doped with the impurity in the initialization semiconductor layer 131d.

The first light emission control thin film transistor T5 includes the first light emission control semiconductor layer 131e, the first light emission control gate electrode 125e, the first light emission control source electrode 176e, and the first light emission control drain electrode 177e. The first light emission control drain electrode 177e corresponds to the first light emission control drain region doped with the impurity in the first light emission control semiconductor layer 131e.

The second light emission control thin film transistor T6 includes the second light emission control semiconductor layer 131f, the second light emission control gate electrode 125f, the second light emission control source electrode 176f, and the second light emission control drain electrode 177f. The second light emission control source electrode 176f corresponds to the second light emission control source region 176f doped with the impurity in the second light emission control semiconductor layer 131f.

The storage capacitor Cst includes a first storage condenser plate 132 and a second storage condenser plate 127 with the gate insulating layer 140 interposed therebetween. Herein, the gate insulating layer 140 is a dielectric material, and a storage capacitance is determined by charges accumulated in the storage capacitor Cst and a voltage between both condenser plates 132 and 127.

The first storage condenser plate 132 is formed on the same layer as the driving semiconductor layer 131a, the switching semiconductor layer 131b, the compensation semiconductor layer 131c, the first light emission control semiconductor layer 131e, and the second light emission control semiconductor layer 131f, and the second storage condenser plate 127 is formed on the same layer as the scan line 121, the prior scan line 122 and the like.

The driving semiconductor layer 131a of the driving thin film transistor T1 connects the switching semiconductor layer 131b and the compensation semiconductor layer 131c and the first light emission control semiconductor layer 131e and the second light emission control semiconductor layer 131f to each other. Therefore, the driving source electrode 176a is connected to the switching drain electrode 177b and the first light emission control drain electrode 177e, and the driving drain electrode 177a is connected to the compensation source electrode 176c and the second light emission control source electrode 176f.

The first storage condenser plate 132 of the storage capacitor Cst is connected to the compensation drain electrode 177c and the initialization drain electrode 177d, and is connected through a connection member 174 to the driving gate electrode 125a. In this case, the connection member 174 is formed on the same layer as the data line 171. The connection member 174 is connected through a contact hole 166 formed in an interlayer insulating layer 160, a first gate insulating layer 141, and a second gate insulating layer 142 to the first storage condenser plate 132, and is connected through a contact hole 167 formed in the interlayer insulating layer 160 to the driving gate electrode 125a.

The second storage condenser plate 127 of the storage capacitor Cst is connected through a contact hole 168 formed in the interlayer insulating layer 160 to the common voltage line 172, and is formed almost parallel to the scan line 121.

A first boosting condenser plate 133 of the boosting capacitor Cb is an extension portion extending from the first storage condenser plate 132, and a second boosting condenser plate 129 is a protruding portion protruding upward and downward from the scan line 121.

The first boosting condenser plate 133 has a hammer shape, and the first boosting condenser plate 133 includes a handle portion 133a that is parallel to the driving voltage line 172 and a head portion 133b formed at an end of the handle portion 133a.

The head portion 133b of the first boosting condenser plate 133 is positioned in the second boosting condenser plate 129 so as to overlap the second boosting condenser plate 129. Therefore, an area of the first boosting condenser plate 133 of the boosting capacitor Cb is smaller than an area of the second boosting condenser plate 129.

Meanwhile, the switching thin film transistor T2 is used as a switching element for selecting the pixel that is to emit light. The switching gate electrode 125b is connected to the scan line 121, the switching source electrode 176b is connected to the data line 171, and the switching drain electrode 177b is connected to the driving thin film transistor T1 and the first light emission control thin film transistor T5. In addition, the second light emission control drain electrode 177f of the second light emission control thin film transistor T6 is directly connected, through a contact hole 181 formed in the protective layer 180, to a pixel electrode 191 of an organic light emitting diode 70.

Hereinafter, referring to FIGS. 4 and 5, the structure of an organic light emitting diode display according to the exemplary embodiment will be described in detail according to the layering order.

In this case, the structure of the thin film transistor will be described based on the driving thin film transistor T1, the switching thin film transistor T2, and the second light emission control thin film transistor T6. In addition, the remaining thin film transistors T3, T4, and T5 are almost the same as the laminate structures of the driving thin film transistor T1, the switching thin film transistor T2, and the second light emission control thin film transistor T6, and thus are not described in further detail.

A buffer layer 111 is formed on the substrate 110, and the substrate 110 is an insulating substrate made of glass, quartz, ceramics, plastics or the like.

The switching semiconductor layer 131b, the driving semiconductor layer 131a, the second light emission control semiconductor layer 131f, and the first boosting condenser plate 133 are formed on the buffer layer 111. The switching semiconductor layer 131b includes a switching source region 132b and a switching drain region 177b facing each other with a switching channel region 131b1 interposed therebetween (see FIG. 5), the driving semiconductor layer 131a includes a driving source region 176a and a driving drain region 177a facing each other with a driving channel region 131a1 interposed therebetween (see FIG. 5), and the second light emission control thin film transistor T6 includes a second light emission control semiconductor layer 131f, which includes a light emission control channel region 13111, the light emission control source region 176f, and the light emission control drain region 133f (see FIG. 4). Impurity doping concentrations of the switching source region 132b, the switching drain region 177b, the driving source region 176a, and the driving drain region 177a may be the same as each other.

The first gate insulating layer 141, formed of silicon nitride (SiNₓ) or silicon oxide (SiO₂), is formed on the switching semiconductor layer 131a, the driving semiconductor layer 131b, the second light emission control semiconductor layer 131f, and the first boosting condenser plate 133.

The scan line 121 including the switching gate electrode 125b and the compensation gate electrode 125c, the prior scan line 122 including the initialization gate electrode 125d, the light emission control line 123 including the first light emission control gate electrode 125e and the second light emission control gate electrode 125f, and a gate wire including the floating gate electrode 25 are formed on the first gate insulating layer 141.

The floating gate electrode 25 is separated from the scan line 121, and the floating gate electrode 25 overlaps the driving channel region 131a1 of the driving semiconductor layer 131a. Furthermore, the switching gate electrode 125a is connected to the scan line 121, and the switching gate electrode 125b overlaps the switching channel region 131b1 of the switching semiconductor layer 131b. In addition, the second light emission control gate electrode 125f overlaps the light emission control channel region 131f1 of the second light emission control semiconductor layer 131f. The gate wire further includes the second storage condenser plate 127 forming the storage capacitor Cst, and the second boosting condenser plate 129 forming the boosting capacitor Cb.

The gate wires 25, 125b, 125c, 125c, 125e, 125f, 121, 122 and 123 and the first gate insulating layer 141 cover the second gate insulating layer 142. The second gate insulating layer 142 is formed of silicon nitride (SiNₓ) or silicon oxide (SiO₂).

The driving gate electrode 125a is formed on the second gate insulating layer 142. The driving gate electrode 125a overlaps the floating gate electrode 25, and an absolute value of a difference between the width W2 of the driving gate electrode 125a and the width W1 of the floating gate electrode 25 may be 4 ?m or less. In the case where the absolute value of the difference between the width W2 of the driving gate electrode 125a and the width W1 of the floating gate electrode 25 is more than 4 ?m, the threshold voltage may be increased, and the channel mobility may be reduced.

As described above, in the driving thin film transistor T1, since the driving gate electrode 125a is formed on the first gate insulating layer 141 and the second gate insulating layer 142, an interval between the driving gate electrode 125a and the driving semiconductor layer 131a becomes broad. Therefore, the driving range of the gate voltage applied to the driving gate electrode 125a can be broadened, the grayscale of light emitted from the organic light emitting diode (OLED) can be more finely controlled by changing the magnitude of the gate voltage, and as a result, it is possible to increase a resolution of the organic light emitting diode display and improve a display quality.

In this case, since only the first gate insulating layer 141 is formed between the switching gate electrode 125b and the switching semiconductor layer 131b, the switching thin film transistor T2 can perform a rapid switching operation.

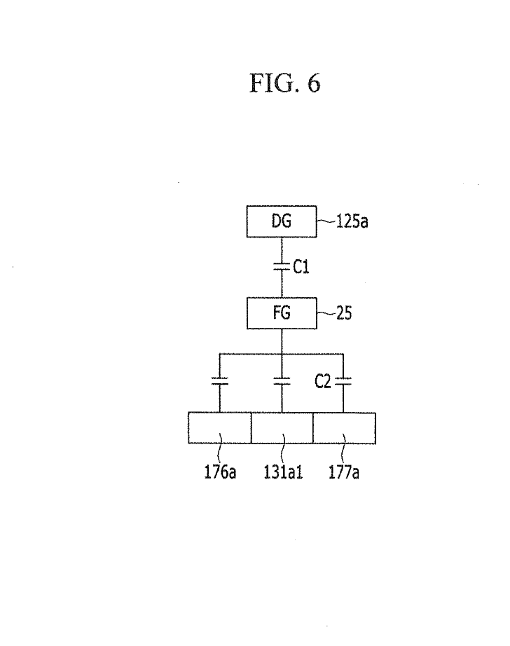

FIG. 6 is a view schematically showing a first floating capacitor and a second floating capacitor of the organic light emitting diode display according to the exemplary embodiment.

As shown in FIG. 6, the first floating capacitor C 1 is formed in the second gate insulating layer 142 formed between the driving gate electrode 125a and the floating gate electrode 25, and the second floating capacitor C2 is formed in the first gate insulating layer 141 formed between the floating gate electrode 25 and the driving drain region 177a of the driving semiconductor layer 131a.

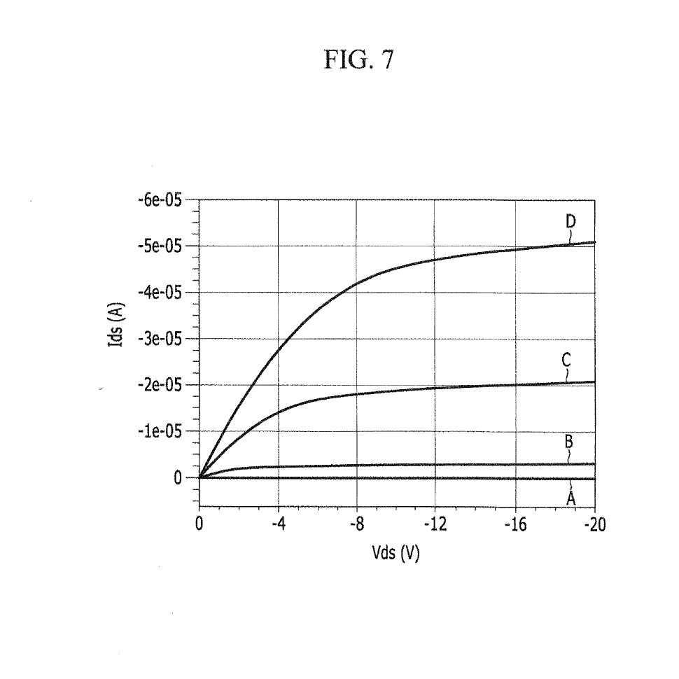

FIG. 7 is a graph showing a driving current according to a driving drain voltage applied to a driving drain electrode of a driving thin film transistor in the organic light emitting diode display according to the exemplary embodiment, and FIG. 8 is a graph showing a driving current according to a driving drain voltage applied to a driving drain electrode of a driving thin film transistor in a known organic light emitting diode display. In the graphs of FIGS. 7 and 8, A, B, C, and D represent driving currents according to driving drain voltages in the cases where the gate voltage Vg is −0.1 V, −5 V, −10 V and −15 V.

As shown in FIG. 7, in the case where the ratio (C2/C1) of the first floating capacitor and the second floating capacitor has a value of 0.125 that is close to 0, since the driving current is constantly maintained as the driving drain voltage is increased, even though the floating gate electrode 25 is formed, the effect applied to the driving current is small.

However, as shown in FIG. 8, in the case where the ratio (C2/C1) of the first floating capacitor and the second floating capacitor has a value of 2, since the driving current is increased as the driving drain voltage is increased, when the floating gate electrode 25 is formed, there is a problem in that the driving current becomes unstable.

Therefore, the ratio (C2/C1) of the first floating capacitor and the second floating capacitor may be more than 0 and less than 2. The first floating capacitor C1 and the second floating capacitor C2 may fluctuate by controlling the thickness d1 of the first gate insulating layer 141 and the thickness d2 of the second gate insulating layer 142, or by controlling materials of the first gate insulating layer 141 and the second gate insulating layer 142.

Meanwhile, the interlayer insulating layer 160 is formed on the second gate insulating layer 142 and the driving gate electrode 125a (see FIG. 5). The first gate insulating layer 141, the second gate insulating layer 142, and the interlayer insulating layer 160 have a contact hole 163 (see FIG. 4) through which the second light emission control drain region 131f1 of the second light emission control semiconductor layer 131f is exposed together. Like the first gate insulating layer 141 and the second gate insulating layer 142, the interlayer insulating layer 160 is made of a ceramic-based material such as silicon nitride (SiNₓ) or silicon oxide (SiO₂).

The data line 171 including the switching source electrode 176b, and data wires including the connection member 174, the second light emission control drain electrode 177f, and the driving voltage line 172, are formed on the interlayer insulating layer 160.

Furthermore, the switching source electrode 176b and the second light emission control drain electrode 177f are connected through contact holes 162 and 163, formed in the interlayer insulating layer 160, the first gate insulating layer 141, and the second gate insulating layer 142, to the switching source region 131b1 of the switching semiconductor layer 131b and the second light emission control drain region 131f1 of the second light emission control semiconductor layer 131f, respectively.

The protective layer 180 covering the data wires 171, 174, 177f, and 172 is formed on the interlayer insulating layer 160, and the pixel electrode 191 is formed on the protective layer 180. The pixel electrode 191 is connected through the contact hole 181 formed in the protective layer 180 to the second light emission control drain electrode 177f.

A barrier rib 350 is formed on an edge of the pixel electrode 191 and the protective layer 180, and the barrier rib 350 has a barrier rib opening 351 through which the pixel electrode 191 is exposed. The barrier rib 350 may be made of resins, such as polyacrylates and polyimides or silica-based inorganic materials.

An organic emission layer 370 is formed on the pixel electrode 191 exposed through the barrier rib opening 351, and the common electrode 270 is formed on the organic emission layer 370. As described above, the organic light emitting diode 70, including the pixel electrode 191, the organic emission layer 370, and the common electrode 270, is formed.

Herein, the pixel electrode 191 is an anode that is a hole injection electrode, and the common electrode 270 is a cathode that is an electron injection electrode. However, the exemplary embodiment according to the present invention is not limited thereto, and the pixel electrode 191 may be the cathode and the common electrode 270 may be the anode according to the driving method of the organic light emitting diode display. Holes and electrons are injected from the pixel electrode 191 and the common electrode 270 into the organic emission layer 370, and when the exciton that is combined with the injected holes and electrons falls from an exited state to a bottom state, light is emitted.

The organic emission layer 370 is formed of a low molecular weight organic material or a high molecular weight organic material such as PEDOT (poly 3,4-ethylenedioxythiophene). Furthermore, the organic emission layer 370 may be formed of a multilayer including one or more of an emission layer, a hole injection layer HIL, a hole transport layer HTL, an electron transport layer ETL, and an electron injection layer EIL. In the case where all the layers are included, the hole injection layer HIL is disposed on the pixel electrode 710 that is the anode, and the hole transport layer HTL, the emission layer, the electron transport layer ETL, and the electron injection layer EIL are sequentially laminated thereon. Since the common electrode 270 is formed of a reflective conductive material, a rear surface light emission type organic light emitting diode display is obtained. Material such as lithium (Li), calcium (Ca), lithium fluoride/calcium (LiF/Ca), lithium fluoride/aluminum (LiF/Al), aluminum (Al), silver (Ag), magnesium (Mg), or gold (Au) may be used as the reflective material.

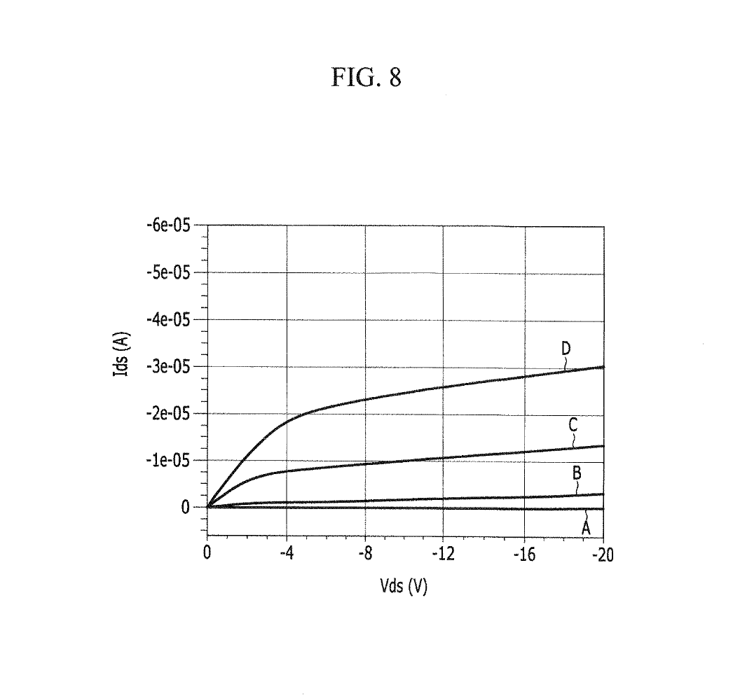

Next, a manufacturing method of the organic light emitting diode display according to the exemplary embodiment shown in FIGS. 1 to 5 will be described in detail with reference to FIGS. 9 to 11.

FIGS. 9 to 11 are cross-sectional views sequentially showing a manufacturing method of a switching thin film transistor and a driving thin film transistor of the organic light emitting diode display according to the exemplary embodiment.

First, as shown in FIG. 9, the switching semiconductor layer 131b and the driving semiconductor layer 131a are formed on the substrate 110. Furthermore, the first gate insulating layer 141 covering the switching semiconductor layer 131b and the driving semiconductor layer 131a is formed. In addition, the switching gate electrode 125b and the floating gate electrode 25 are formed on the first gate insulating layer 141. In this case, the switching gate electrode 125b and the floating gate electrode 25 are formed at positions partially overlapping the switching semiconductor layer 131b and the driving semiconductor layer 131a, respectively.

The switching gate electrode 125b is formed so as to be connected to the scan line 121, and formed on the same layer as the scan line 121. Furthermore, the floating gate electrode 25 is formed so as to be separated from the scan line 121, and is formed on the same layer as the scan line 121.

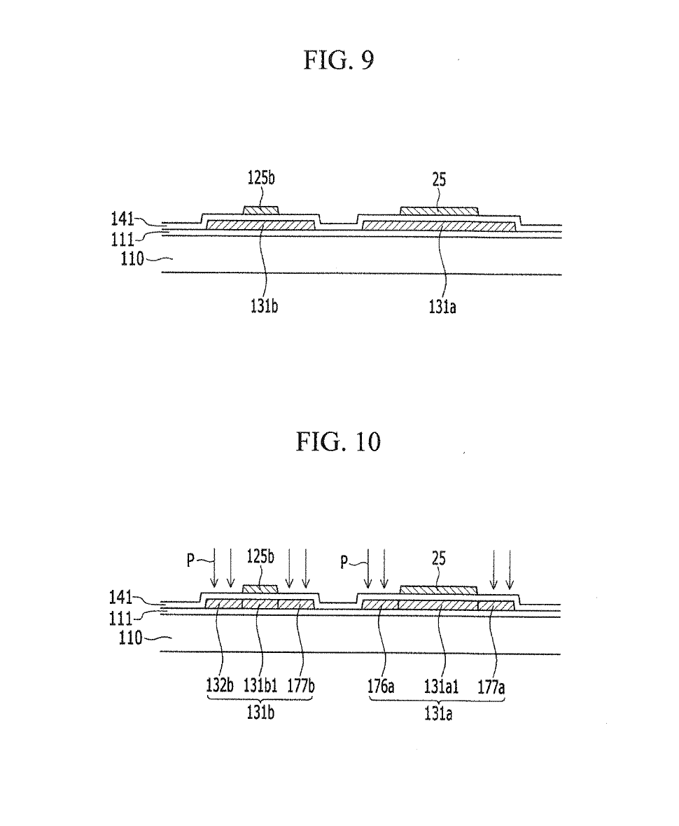

Next, as shown in FIG. 10, an impurity is doped on the switching semiconductor layer 131b and the driving semiconductor layer 131a by using the switching gate electrode 125b and the floating gate electrode 25 as the mask. Therefore, the switching source region 132b and the switching drain region 177b are formed in the switching semiconductor layer 131b, and the driving source region 176a and the driving drain region 177a are formed in the driving semiconductor layer 131a.

In this case, the doped impurity passes through only the first gate insulating layer 141 formed on the switching semiconductor layer 131b and the driving semiconductor layer 131a so as to form the switching source region 132b and the switching drain region 177b and the driving source region 176a and the driving drain region 177a in the switching semiconductor layer 131b and the driving semiconductor layer 131a, respectively, so that impurity doping may be smoothly performed. Therefore, impurity doping concentrations of the switching source region 132b, the switching drain region 177b, the driving source region 176a, and the driving drain region 177a may be the same as each other, and since a doping acceleration voltage does not need to be increased, it is easy to perform the manufacturing process. Furthermore, since the second gate insulating layer 142 may be formed so as to be thick regardless of the impurity doping concentration, the driving range of the driving thin film transistor T1 may be broadened.

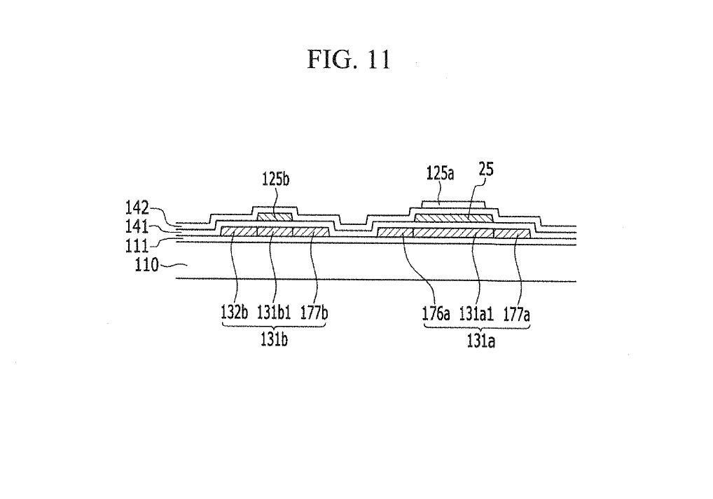

Next, as shown in FIG. 11, the second gate insulating layer 142 covering the first gate insulating layer 141, the switching gate electrode 125b, and the floating gate electrode 25 is formed. Furthermore, the driving gate electrode 125a is formed on the second gate insulating layer 142. In this case, the driving gate electrode 125a is formed at a position corresponding to the floating gate electrode 25.

As described above, it is possible to form a driving semiconductor layer so that the impurity doping concentration of the driving semiconductor layer 131a is the same as that of the switching semiconductor layer 131b while broadening the driving range by forming the floating gate electrode 25 on the driving semiconductor layer 131a so as to perform an impurity doping process and forming the second gate insulating layer 142 and the driving gate electrode 125a on the floating gate electrode 25 so as to overlap each other.

Next, the interlayer insulating layer 160 is formed on the second gate insulating layer 142 and the driving gate electrode 125a (as seen in FIG. 5). Furthermore, the data line 171 and the driving voltage line 172 crossing the scan line 121 and transferring the data signal Dm and the driving voltage ELVDD, respectively, are formed on the interlayer insulating layer 160, the protective layer 180 covering upper sides of the data line 171 and the driving voltage line 172 is formed (as seen in FIG. 4), and the organic light emitting diode (OLED) connected to the driving thin film transistor T1 is formed on the protective layer 180.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode display, comprising:
a substrate;
a scan line formed on the substrate and transferring a scan signal;
a data line and a driving voltage line crossing the scan line and transferring a data signal and a driving voltage, respectively;
a switching thin film transistor connected to the scan line and the data line;
a driving thin film transistor connected to the switching thin film transistor and the driving voltage line; and
an organic light emitting diode connected to the driving thin film transistor;
the driving thin film transistor including:
a driving semiconductor layer including a driving channel region, a driving source region and a driving drain region, the driving channel region being interposed between the driving source region and the driving drain region;
a first gate insulating layer covering the driving semiconductor layer;
a floating gate electrode formed on the first gate insulating layer and formed at a position corresponding to the driving channel region;
a second gate insulating layer covering the first gate insulating layer and the floating gate electrode; and
a driving gate electrode formed on the second gate insulating layer and formed at a position corresponding to the floating gate electrode.

2. The organic light emitting diode display of claim 1, impurity doping concentrations of the switching source region, the switching drain region, the driving source region, and the driving drain region being the same as each other.

3. The organic light emitting diode display of claim 2, an absolute value of a difference between a width of the driving gate electrode and the width of the floating gate electrode being no greater than 4 μm.

4. The organic light emitting diode display of claim 1, a first floating capacitor being formed between the driving gate electrode and the floating gate electrode and being defined by C1, a second floating capacitor being formed between the floating gate electrode and the drain region and being defined by C2, and a ratio C2/C1 of the first floating capacitor and the second floating capacitor being more than 0 and less than 2.

5. The organic light emitting diode display of claim 1, the switching thin film transistor including:
a switching semiconductor layer including a switching channel region, a switching source region, and a switching drain region, the switching channel region being interposed between the switching channel region and the switching source region; and
a switching gate electrode formed on the first gate insulating layer covering the switching semiconductor layer and being formed at a position corresponding to the switching channel region;
the first gate insulating layer and the floating gate electrode covering the second gate insulating layer.

6. The organic light emitting diode display of claim 5, the switching gate electrode being connected to the scan line, and the floating gate electrode being separated from the scan line.

7. A manufacturing method of an organic light emitting diode display, comprising the steps of:
forming a switching semiconductor layer and a driving semiconductor layer on a substrate;
forming a first gate insulating layer covering the switching semiconductor layer and the driving semiconductor layer;
forming a switching gate electrode and a floating gate electrode at positions partially overlapping the switching semiconductor layer and the driving semiconductor layer, respectively, on the first gate insulating layer;
doping an impurity on the switching semiconductor layer and the driving semiconductor layer by using the switching gate electrode and the floating gate electrode as a mask to form a switching source region and a switching drain region and a driving source region and a driving drain region, respectively;
forming a second gate insulating layer covering the first gate insulating layer, the switching gate electrode, and the floating gate electrode; and
forming a driving gate electrode at a position corresponding to the floating gate electrode on the second gate insulating layer.

8. The manufacturing method of an organic light emitting diode display of claim 7, impurity doping concentrations of the switching source region, the switching drain region, the driving source region, and the driving drain region being the same as each other.

9. The manufacturing method of an organic light emitting diode display of claim 8, the switching gate electrode being connected to a scan line transferring a scan signal and being formed on the same layer as the scan line.

10. The manufacturing method of an organic light emitting diode display of claim 9, the floating gate electrode being formed so as to be separated from the scan line.

11. The manufacturing method of an organic light emitting diode display of claim 10, further comprising the steps of:
forming an interlayer insulating layer on the second gate insulating layer and the driving gate electrode;
forming a data line and a driving voltage line crossing the scan line and transferring a data signal and a driving voltage, respectively, on the interlayer insulating layer;
forming a protective layer covering upper portions of the data line and the driving voltage line; and
forming an organic light emitting diode connected to the driving thin film transistor on the protective layer.
